(19) United States
(12) Patent Application Publication
(10) Pub. No.: US 2005/0168141 A1
(43) Pub. Date: Aug. 4, 2005

(54) Method for producing an electronic component and a display

(75) Inventors: Debora Henseler, Erlangen (DE); Georg Wittmann, Herzogenaurach (DE); Ralph Patzold, Roth (DE); Karsten Heuser, Erlangen (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/025,281

(22) Filed: Dec. 28, 2004

(30) Foreign Application Priority Data
Dec. 31, 2003 (DE) 103 61 790.6

(51) Int. Cl. H01L 21/68

(52) U.S. Cl. 313/506

(57) ABSTRACT

The production of electronic and/or optoelectronic components on a flexible film (1) can be adapted without a high effort to existing installations, which are usually based on a batch process, by virtue of the fact that, during the production method, the flexible film (1) is fixed on a carrier (2), which is sufficiently mechanically stable for the further processing of the film (1). The film (1) is connected to the carrier (2) by a magnetic layer (3) or a thermoplastic material. After the further processing of the film (1), the carrier (2) can be removed from the film (2) in a state in which it can be reused.

### RELATED APPLICATIONS

This patent application claims the priority of German patent application 10361790.6, the disclosure content of which is hereby incorporated by reference.

### FIELD OF THE INVENTION

The invention relates to an electronic component comprising a flexible substrate, and to a method for producing such a component. The invention also relates to a display based on a flexible substrate and to a method for producing such a display.

### BACKGROUND OF THE INVENTION

Known methods and installations for producing electronic components primarily proceed from a rigid substrate or carrier of the component and are almost exclusively designed as so-called batch processes. By way of example, rigid glass substrates are generally used for the production of organic LEDs.

An economically expedient batch method for producing electronic, in particular optoelectronic, components on flexible substrates has not been disclosed heretofore. The previous methods based on rigid substrates are generally unsuitable for handling flexible substrates.

It is desirable for the handling of flexible substrates for producing electronic, in particular optoelectronic, components on such substrates to be adapted to already existing manufacturing installations provided for batch processes. This obviates a high outlay for development and construction of new installations specially geared to the production of components with flexible substrates.

### SUMMARY OF THE INVENTION

One object of the present invention is to provide a method of the type mentioned in the introduction which enables the use of conventional batch processes. Another object of the present invention is to provide an organic light-emitting diode arrangement (OLED) and a display which can be produced according to such a method.

These and other objects are attained in accordance with one aspect of the present invention directed to a method for producing an electronic component is specified. In a first step of the method, a flexible substrate is provided in this case. In a next step, the flexible substrate is connected to a process carrier, which is mechanically more stable than the flexible substrate. In a subsequent method step, an electronic component is formed on the flexible substrate. Finally, the process carrier is removed from the flexible substrate.

It is important that the steps of the method described proceed in the order presented. It is possible, moreover, for further intermediate steps to be integrated into the method.

The process carrier described is particularly distinguished by the fact that it is sufficiently mechanically stable to enable processing of the flexible substrate.

The connection between the process carrier and the flexible substrate is preferably configured in a releasable fashion. By way of example, such a connection may be imparted by a magnetic force between substrate and process carrier. In this case, the connection between substrate and process carrier must be strong enough to enable processing of the flexible substrate. Once the electronic component has then been formed on the flexible substrate, the process carrier can be released relatively easily from the substrate without the substrate or the process carrier being damaged in doing so. In this way, the same process carrier can be utilized a number of times.

In the method, a flexible substrate is fixed on a comparatively rigid process carrier by means of a rereleasable adhesion, i.e. the process carrier is more rigid than the flexible substrate and thus sufficiently mechanically stable for the further processing of the substrate and thus also mechanically more stable than the flexible substrate. The process carrier preferably has similar chemical and physical properties to the flexible substrate. Usually, the flexible substrates are polymer-based and can have a variety of thicknesses and be formed as a layer sequence.

What is advantageous about the method described is that the process carrier, because of the rereleasable connection to the substrate, can be removed again from the latter completely or almost completely. The process carrier can then be reused without a high effort.

In the method described, the flexible substrate may undergo conventional processes known for example from the processing of organic light-emitting diodes on glass substrates in existing manufacturing installations, including lithography, solution and cleaning baths, vacuum steps, but also printing processes on the process carrier. The flexible substrate can be removed again from the process carrier at the end of processing, that is to say after the encapsulation of the electronic or optoelectronic components.

In the case of a magnetic adhesion between substrate and process carrier, after running through the complete process for producing the component on or in the substrate, the process carrier can be stripped again from the substrate without any residues. The process carrier can be separated from the substrate simply by being pulled away.

What is advantageous about a connection between substrate and process carrier by means of a thermoplastic material is that thermoplastic material can be removed largely without any residues, and without a high effort, from a polymer-based film and for example a glass substrate as carrier. In order to remove the process carrier from the substrate, the thermoplastic material is preferably melted. The process carrier and the substrate are then pulled away from one another.

In a preferred embodiment, an area region or a plurality of area regions of the substrate is or are fixed on the process carrier, the area region or the area regions forming a grid-like pattern. Such a grid-like pattern may have a plurality of quadrangular, square, triangular units or units of other shapes. The size of these units may correspond to the size of the finished components or contain a plurality of finished components.

According to another aspect of the invention, the method described above is used for producing a display having a flexible film.

Another aspect of the present invention is directed to an optoelectronic element having at least one layer sequence containing an active zone, and a flexible substrate, on which the layer sequence is arranged, wherein the substrate at least partly has a magnetic or magnetizable layer on its substrate side remote from the layer sequence.

A further aspect of the present invention is directed to a display having a flexible substrate, which has a front side and a rear side, a radiation-generating display element being arranged on the front side, wherein the rear side at least partly has a magnetic or magnetizable layer.

### BRIEF DESCRIPTION OF THE DRAWINGS

FIGS. 1a and 1b respectively show a diagrammatic plan view and side view of a flexible film together with functional layers which are processed according to a first exemplary embodiment of the method according to the invention,

FIGS. 2a and 2b respectively show a diagrammatic plan view and side view of a flexible film together with functional layers which are processed according to a second exemplary embodiment of the method according to the invention,

FIGS. 3a and 3b respectively show a diagrammatic plan view and sectional view of a flexible film together with functional layers which are processed according to a third exemplary embodiment of the method according to the invention, and

FIG. 4 shows a diagrammatic plan view of a flexible film together with functional layers which are processed according to a fourth exemplary embodiment of the method according to the invention.

### DETAILED DESCRIPTION OF THE DRAWINGS

In the exemplary embodiments, identical or identically acting constituent parts are provided with identical reference symbols. In principle, the figures are not to be regarded as true to scale. In principle, the individual constituent parts are also not illustrated with the actual relative sizes with respect to one another.

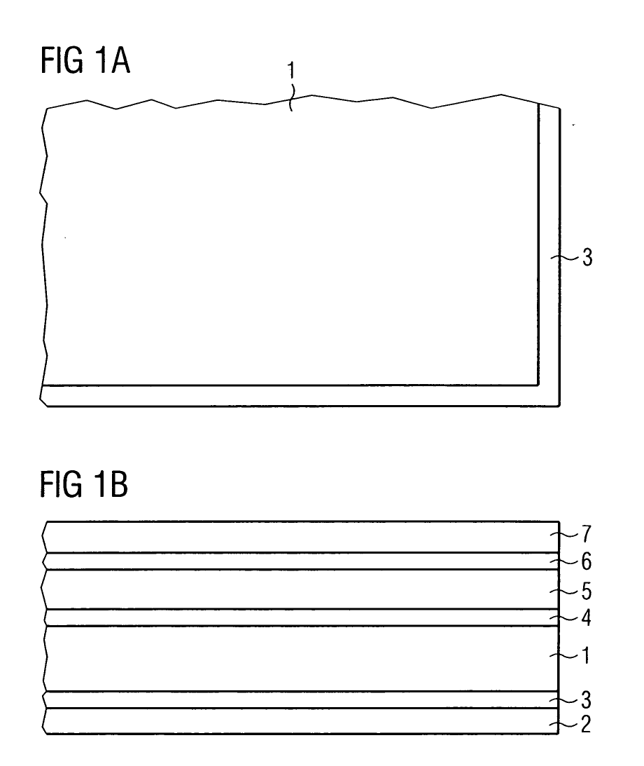

FIG. 1a illustrates a flexible film 1, which, in this first exemplary embodiment of the methods according to the invention, is used for producing a flexible OLED (organic light-emitting diode) display.

The film comprises for example a flexible polymer or a polymer mixture which is flexible. Before the further processing of the film, a magnetic layer 3 is applied on a side of the film 1 which is not provided for the application of further e.g. functional layers. The magnetic layer 3 may be applied by means of vapor deposition or sputtering, if appropriate in conjunction with a corresponding mask. In this example, the magnetic layer 3 has permalloy (namely an alloy comprising approximately 21.5% Fe and approximately 78.5% Ni) and is applied only at the edge region of the film 1. The thickness of the magnetic layer 3 depends on parameters such as the specific holding force of the magnet and the process carrier 2.

FIG. 1b shows the film 1 after or during the further processing for producing an OLED display. Before the further processing of the film 1, a mechanically stable process carrier 2 which adheres magnetically is brought into contact with the film 1. By means of magnetic adhesion, the process carrier 2 is fixed on the magnetic layer 3 and therefore indirectly on the film 1. The process carrier 2 is preferably formed as a plate.

The film 1 strengthened in this way may then be subjected for example to a conventional batch process for producing an OLED display. FIG. 1b shows the film 1 after such processing. Firstly, a transparent electrically conductive layer 4 is applied, for example in strip form, to the film 1. Said transparent layer 4 usually has indium tin oxide (ITO) and serves as an anode. The functional organic layers 5 are applied to the transparent anode 4 and a usually metallic cathode 6 is applied to the functional organic layers 5. The cathode 6 is generally in strip form as well, the strips of the cathode 6 essentially running perpendicular to the strips of the anode 4. Finally, a cap or encapsulation layer 7 is typically applied to the cathode 6. It is also possible to apply a layer sequence of encapsulation layers 7 to the cathode 6. The process carrier 2 may be pulled away from the magnetic layer 3 before or after the application of the encapsulation layer 7. The process carrier 2 may then be reused in the process without a further effort. The process carrier 2 is preferably separated from the film 1 before the singulation of the film 1 in a plurality of displays.

Depending on the size and weight of the film 1, the magnetic layer 3 may be applied only at the edge region of the film 1. Generally, a fixing only at the edge region of the film 1 suffices if the surface of the film 1 is relatively small or the film 1 is relatively light. By way of example, a permalloy magnetic layer 3 having a width of 10 mm and a thickness of 500 nm at the edge of a 15 cm×15 cm film 1 made of a PET (Polyethylene Terephthalate) having a thickness of 100 μm suffices to hold the latter on a 5 mm thick process carrier 2 made of steel ST37 which also has a size of approximately 15 cm×15 cm. Further magnetic materials such as iron, nickel and alnico are also suitable as material for the process carrier 2.

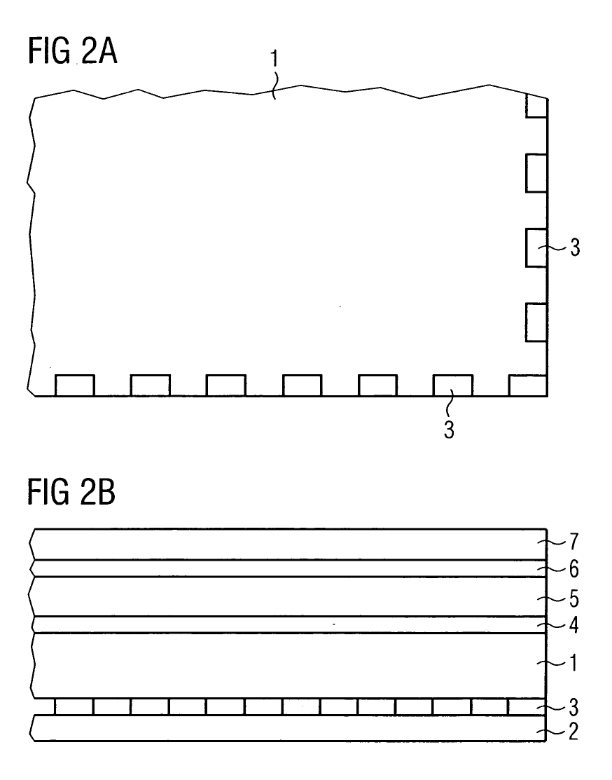

The film 1 shown in FIGS. 2a and 2b differs from the film 1 illustrated in FIG. 1a merely by virtue of the fact that the magnetic layer 3 does not run continuously at the edge region of the film 1, but rather is interrupted. The magnetic layer 3 in this second exemplary embodiment of the invention is formed as a plurality of magnetic layer parts. The configuration of the magnetic layer 3 in such a pattern may be possible if sufficient magnetic holding force is present despite the reduced contact area between the magnetic layer 3 and the process carrier 2. This has the advantage that less magnetic material is required, which may reduce the material costs. In addition, the proportion of the film 1 which is available as an active area is larger than the proportion covered with a continuous magnetic layer 3.

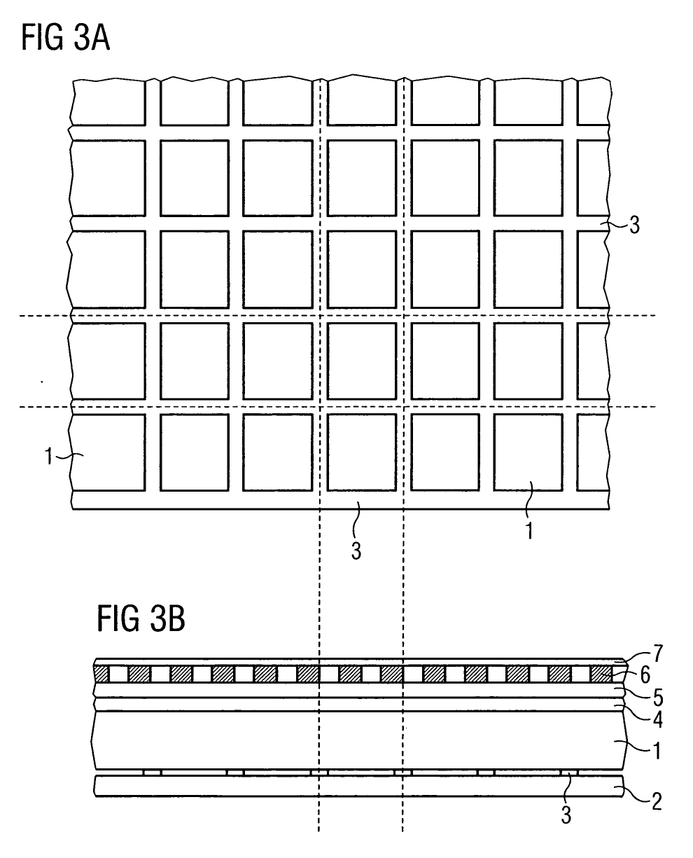

FIGS. 3a and 3b show a third exemplary embodiment of the invention, in which the magnetic layer 3 is not only formed at the edge region of the film 1. In this case, the magnetic layer 3 has a regular grid-like pattern over the entire surface of the film 1. By way of example, the repeating units of the grid-like pattern are square in this case (see FIG. 3a). Other shapes of the grid-forming units such as triangular, quadrangular, hexagonal, circular are also conceivable.

The configuration of the magnetic layer 3 as a grid-like pattern is suitable in particular for large-area films 1. By virtue of the grid-like magnetic layer 3, the weight of the process carrier 2 that is to be held can be distributed better and therefore be borne more firmly. Unfavorable stripping away of the process carrier 2 from the magnetic layer 3 or the film 1 during the further processing of the film 1 is then less likely.

The size of the grid-forming units may correspond to the size of one or more finished displays or one or more finished components. By way of example, the film 1 illustrated in FIGS. 3a and 3b is singulated along the magnetic layer 3 or the broken line illustrated in FIGS. 3a and 3b. In this case, one grid-forming unit of the magnetic layer 3 corresponds to one display. The film 1 may simply be cut up for this purpose; the magnetically coated grid may optionally be removed in this case.

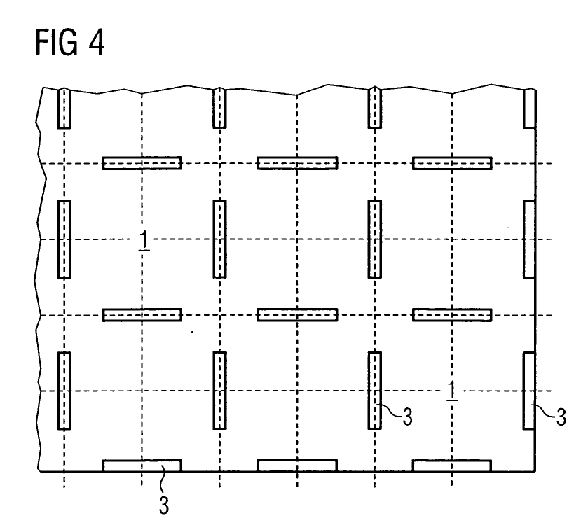

FIG. 4 shows a variant of the exemplary embodiment illustrated in FIGS. 3a and 3b. In this case, the magnetic layer 3 is not formed as a continuous layer in a grid-like pattern, but rather as an interrupted layer in a grid-like pattern. All the patterns mentioned in conjunction with FIGS. 3a and 3b may also be formed as an interrupted magnetic layer 3. As already mentioned above in connection with FIGS. 2a and 2b, this has the advantage of requiring less magnetic material. The film 1 may be singulated along the broken line which is illustrated in FIG. 4 and corresponds in part to the magnetic layer 3, except for the edge region. In this example, one grid-forming unit of the magnetic layer 3 comprises four displays.

In all the examples described above, it is optionally possible for the residual parts of the magnetic layer 3 to be removed after singulation.

The configuration of the magnetic layer 3 in the exemplary embodiments described above may also apply analogously to an embodiment of the invention in which the process carrier 2 is fixed to the film 1 by means of a thermoplastic material. The thermoplastic material may then be applied or coated onto the film 1 in accordance with the patterns of the magnetic layer 3 explained above. The thermoplastic material may be connected to a stable process carrier 2 (e.g. a glass plate) for example by means of ultrasonic welding or resistance heating (heating press). The thermoplastic material preferably liquefies as a result of the heating (e.g. between 100° C. and 200° C.). The connection between the thermoplastic material and the process carrier solidifies through cooling of the thermoplastic material.

After the further processing of the film 1, the thermoplastic material may be removed again thermally from the film 1 and from the process carrier 2. Unlike in the case of the adhesive according to the prior art, the thermoplastic material can be removed from the film 1 and the process carrier 2 without any residues. Consequently, the thermoplastic material cannot form a disturbance in the finished product and the process carrier can be reused without any further effort.

In a similar manner, the patterns of the magnetic layer 3 explained above may also be used for an embodiment of the invention in which area regions of the film 1 are melted and the film 1 is connected to a process carrier 2 as a result of the melting. Said area regions may be defined in accordance with the patterns of the magnetic layer 3. The melting can be performed, for example, by the above-mentioned ultrasonic welding or resistance heating (e.g. using a heating press).

In order to remove the process carrier from the substrate, the area region where substrate and process carrier are joined can be melted. Substrate and process carrier are then pulled away from each other. The melting can be performed, for example, as explained above.

The invention is not restricted by the description on the basis of the exemplary embodiments. Rather, the invention encompasses any new feature and also any combination of features, which in particular comprises any combination of features in the patent claims, even if said feature or said combination is itself not explicitly specified in the patent claims or exemplary embodiments.

1. A method for producing an electronic component, comprising the following steps of
providing a flexible substrate (1),
connecting the flexible substrate (1) to a process carrier (2), which is mechanically more stable than the flexible substrate (1),
forming an electronic component on the flexible substrate (1),
removing the process carrier (2) from the flexible substrate (1).

2. The method as claimed in claim 1,
in which the process carrier is sufficiently mechanically stable for the further processing of the substrate (1) for forming the electronic component on the substrate (1).

3. The method as claimed in claim 1,
in which the flexible substrate (1) is provided with at least one magnetic or magnetizable material layer and the process carrier comprises at least one means which is used to hold the flexible substrate (1) during the further processing thereof by magnetic adhesion on the process carrier (2).

4. The method as claimed in claim 1,
in which a magnetic or magnetizable layer (3) is applied or fixed on the substrate (1) and the process carrier (2) comprises a material or a material mixture which is magnetic or magnetizable.

5. The method as claimed in claim 4,
in which the magnetic or magnetizable layer (3) is applied by means of vapor deposition or sputtering onto the substrate (1).

6. The method as claimed in claim 4,
in which the magnetic or magnetizable layer (3) is fixed to the substrate (1) by means of an adhesive.

7. The method as claimed in claim 4,
in which the magnetic or magnetizable layer (3) has a plurality of separate layer parts.

8. The method as claimed in claim 4,
in which the substrate (1) is pulled away from the process carrier (2) after the further processing of said substrate.

9. The method as claimed in claim 1,
in which the substrate (1) is fixed on the process carrier (2) by means of a thermoplastic material.

10. The method as claimed in claim 9,
in which the thermoplastic material is placed between the substrate (1) and the process carrier (2) and the thermoplastic material is initially momentarily melted for the purpose of producing a connection between substrate and process carrier.

11. The method as claimed in claim 9,
in which, in order to remove the process carrier (2) from the substrate (1) after the further processing thereof, the thermoplastic material is melted again and the substrate is pulled away.

12. The method as claimed in claim 1,
in which the substrate (1) is fixed on the process carrier (2) by melting at least one area region of the substrate (1) which bears on the process carrier.

13. The method as claimed in claim 12,
in which the process carrier (2) is removed from the substrate (1) by separation of the area region.

14. The method as claimed in claim 1,
in which the substrate (1) is fixed on the process carrier (2) at the edge region of said substrate.

15. The method as claimed in claim 1,
in which the substrate contains at least one polymer.

16. The method as claimed in claim 1,
in which the electronic component is an optoelectronic component.

17. The method as claimed in claim 1,
in which the substrate (1) is fixed on the process carrier (2) in one or more area regions of the substrate (1), the area region or the area regions forming a grid-like pattern.

18. The application of the method as claimed in claim 1 for producing a display having a flexible substrate (1).

19. An optoelectronic element having at least one layer sequence containing an active zone, and a flexible substrate (1), on which the layer sequence is arranged,
wherein
the substrate (1) at least partly has a magnetic or magnetizable layer (3) on its substrate side remote from the layer sequence.

20. The optoelectronic element as claimed in claim 19,
in which the active zone is a radiation-generating region.

21. The optoelectronic element as claimed in claim 19,
in which the active zone is a radiation-receiving region.

22. A display having a flexible substrate, which has a front side and a rear side, a radiation-generating display element being arranged on the front side,
wherein
the rear side at least partly has a magnetic or magnetizable layer (3).
